(19) United States
(12) Patent Application Publication
(10) Pub. No.: US 2018/0166419 A1
(43) Pub. Date: Jun. 14, 2018

(54) SEMICONDUCTOR PACKAGE

(71) Applicant: NANYA TECHNOLOGY CORPORATION, TAOYUAN CITY (TW)

(72) Inventor: PO-CHUN LIN, CHANGHUA CITY (TW)

(21) Appl. No.: 15/375,498

(22) Filed: Dec. 12, 2016

(51) Int. Cl. H01L 25/065; H01L 23/31; H01L 23/00; H01L 23/522

(52) U.S. Cl. CPC H01L 25/0655; H01L 23/3107; H01L 24/17; H01L 2224/0401; H01L 24/05; H01L 2224/1703; H01L 23/5226

(57) ABSTRACT

A semiconductor package includes a first device; a second device laterally adjacent to the first device; a molding member encapsulating the first device and the second device; and a lateral bump structure implementing a lateral signal path between the first device and the second device. A portion of the molding member is disposed between the first device and the second device.

### TECHNICAL FIELD

The present disclosure relates to a semiconductor package, and particularly relates to a semiconductor package having a bump structure implementing a lateral signal path between two laterally adjacent chips or between a chip and a conductive via.

### DISCUSSION OF THE BACKGROUND

Semiconductor devices are essential for many modern applications. With the advancement of electronic technology, semiconductor devices are becoming smaller in size while having greater functionality and greater amounts of integrated circuitry. Due to the miniaturized scale of semiconductor devices, chip-on-chip technique is now widely used for manufacturing semiconductor devices. Numerous manufacturing steps are undertaken in the production of such semiconductor package.

However, the manufacturing of semiconductor devices in a miniaturized scale is becoming more complicated. An increase in the complexity of manufacturing semiconductor devices may cause deficiencies such as poor electrical interconnection, development of cracks, or delamination of components. As such, there are many challenges for modifying the structure and manufacture of semiconductor devices.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor package comprising: a first device; a second device laterally adjacent to the first device; a molding member encapsulating the first device and the second device; and a lateral bump structure implementing a lateral signal path between the first device and the second device; wherein a portion of the molding member is disposed between the first device and the second device.

In some embodiments, the first device and the second device are two adjacent semiconductor chips of a single wafer.

In some embodiments, the first device and the second device are two semiconductor chips from different wafers.

In some embodiments, the first device is a semiconductor chip and the second device is a conductive via.

In some embodiments, the lateral bump structure comprises: an under bump metallization electrically connecting the first device and the second device in the absence of a redistribution structure; and a bump body disposed over the under bump metallization.

In some embodiments, the lateral bump structure comprises: an under bump metallization electrically connecting the first device and the second device in the absence of a redistribution structure; a conductive pillar disposed over the under bump metallization; and a bump body disposed over the conductive pillar.

In some embodiments, the semiconductor package further comprises a vertical bump structure implementing a vertical signal path of the first device, wherein a height of the vertical bump structure is different from a height of the lateral bump structure.

In some embodiments, the vertical bump structure is higher than the lateral bump structure.

In some embodiments, the bump structure implements the lateral signal path between the first device and the second device in the absence of a redistribution structure. Consequently, the height of the semiconductor package of the present disclosure is less than the height of the semiconductor package with a redistribution structure. In other words, the semiconductor package of the present disclosure can meet the miniaturized scale demand (small form factor) of the modern semiconductor packages. In addition, the absence of the redistribution structure is a key factor in the reduction of the fabrication cost of the semiconductor package.

Another aspect of the present disclosure provides a semiconductor package, comprising: a first device; a second device laterally adjacent to the first device; a molding member encapsulating the first device and the second device, wherein a portion of the molding member is disposed between the first device and the second device; and an integrated signal path comprising a redistribution structure implementing a lateral signal path and a first bump structure implementing a first vertical signal path, wherein the redistribution structure comprises a conductive line electrically connecting the first device and the second device, and the first bump structure is electrically connected to the conductive line.

In some embodiments, the first device and the second device are two adjacent semiconductor chips of a single wafer.

In some embodiments, the first device and the second device are two semiconductor chips from different wafers.

In some embodiments, the first device is a semiconductor chip and the second device is a conductive via.

In some embodiments, the first bump structure comprises: an under bump metallization electrically connecting the first device and the second device; and a bump body disposed over the under bump metallization.

In some embodiments, the first bump structure comprises: an under bump metallization electrically connecting the first device and the second device; a conductive pillar disposed over the under bump metallization; and a bump body disposed over the conductive pillar.

In some embodiments, the semiconductor package further comprises a second bump structure implementing a second vertical signal path of the first device, wherein a height of the first bump structure is different from a height of the second bump structure.

In some embodiments, the second bump structure is higher than the first bump structure.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures.

FIG. 1 is a cross-sectional view of a semiconductor package in accordance with a comparative embodiment of the present disclosure.

FIG. 2 is a cross-sectional view of a semiconductor package in accordance with some embodiments of the present disclosure.

FIG. 3A is a cross-sectional view of the lateral signal path implemented by the lateral bump structure in accordance with some embodiments of the present disclosure.

FIG. 3B is a cross-sectional view of an integrated signal path implemented by a bump structure and a redistribution structure in accordance with some embodiments of the present disclosure.

FIG. 4 is a cross-sectional view of a semiconductor package in accordance with some embodiments of the present disclosure.

FIG. 5 is a cross-sectional view of a semiconductor package in accordance with some embodiments of the present disclosure.

FIG. 6A is a cross-sectional view of the lateral signal path implemented by the first lateral bump structure in accordance with some embodiments of the present disclosure.

FIG. 6B is a cross-sectional view of an integrated signal path implemented by a bump structure and a redistribution structure in accordance with some embodiments of the present disclosure.

FIG. 7A is a cross-sectional view of the lateral signal path implemented by the first lateral bump structure in accordance with some embodiments of the present disclosure.

FIG. 7B is a cross-sectional view of an integrated signal path implemented by a bump structure and a redistribution structure in accordance with some embodiments of the present disclosure.

FIG. 8A is a cross-sectional view of the lateral signal path implemented by the first lateral bump structure in accordance with some embodiments of the present disclosure.

FIG. 8B is a cross-sectional view of an integrated signal path implemented by a bump structure and a redistribution structure in accordance with some embodiments of the present disclosure.

FIG. 9 is a cross-sectional view of a semiconductor package in accordance with some embodiments of the present disclosure.

FIG. 10 is a flow chart of a method for preparing a semiconductor package in accordance with some embodiments of the present disclosure.

FIGS. 11 to 16 are schematic views of a process for preparing the semiconductor package by the method of FIG. 10 in accordance with some embodiments of the present disclosure.

### DETAILED DESCRIPTION

The following description of the disclosure accompanies drawings, which are incorporated in and constitute a part of this specification, and which illustrate embodiments of the disclosure, but the disclosure is not limited to the embodiments. In addition, the following embodiments can be properly integrated to complete another embodiment.

References to “one embodiment,” “an embodiment,” “exemplary embodiment,” “other embodiments,” “another embodiment,” etc. indicate that the embodiment(s) of the disclosure so described may include a particular feature, structure, or characteristic, but not every embodiment necessarily includes the particular feature, structure, or characteristic. Further, repeated use of the phrase “in the embodiment” does not necessarily refer to the same embodiment, although it may.

The present disclosure is directed to a semiconductor package having a bump structure implementing a lateral signal path between two laterally adjacent chips or between a chip and a conductive via. In order to make the present disclosure completely comprehensible, detailed steps and structures are provided in the following description. Obviously, implementation of the present disclosure does not limit special details known by persons skilled in the art. In addition, known structures and steps are not described in detail, so as not to unnecessarily limit the present disclosure. Preferred embodiments of the present disclosure will be described below in detail. However, in addition to the detailed description, the present disclosure may also be widely implemented in other embodiments. The scope of the present disclosure is not limited to the detailed description, and is defined by the claims.

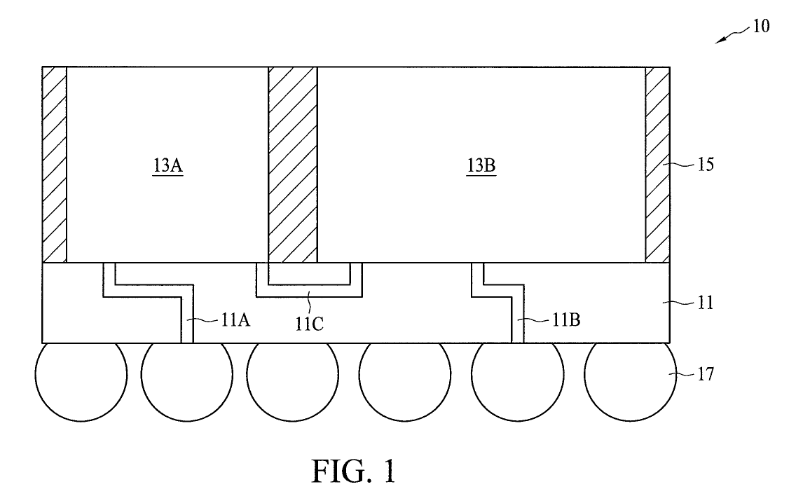

FIG. 1 is a cross-sectional view of a semiconductor package 10 in accordance with a comparative embodiment of the present disclosure. The semiconductor package 10 includes a redistribution layer 11, a semiconductor chip 13A and a semiconductor chip 13B disposed on the redistribution layer 11, a molding member 15 encapsulating the semiconductor chip 13A and the semiconductor chip 13B on the redistribution layer 31, and a plurality of conductive bumps 17 attached to the redistribution layer 11. In some embodiments, the conductive bumps 17 are disposed on the bottom side of the redistribution layer 11, while the semiconductor chip 13A and the semiconductor chip 13B are disposed on the upper side of the redistribution layer 11.

In some embodiments, a vertical signal path of the semiconductor chip 13A is implemented by a conductive line 11A in the redistribution layer 11 and the conductive bump 17, a vertical signal path of the semiconductor chip 13B is implemented by a conductive line 11B in the redistribution layer 11 and the conductive bump 17, and a lateral signal path between the semiconductor chip 13A and the semiconductor chip 13B is implemented by a conductive line 11C in the redistribution layer 11 in the absence of the conductive bump 17.

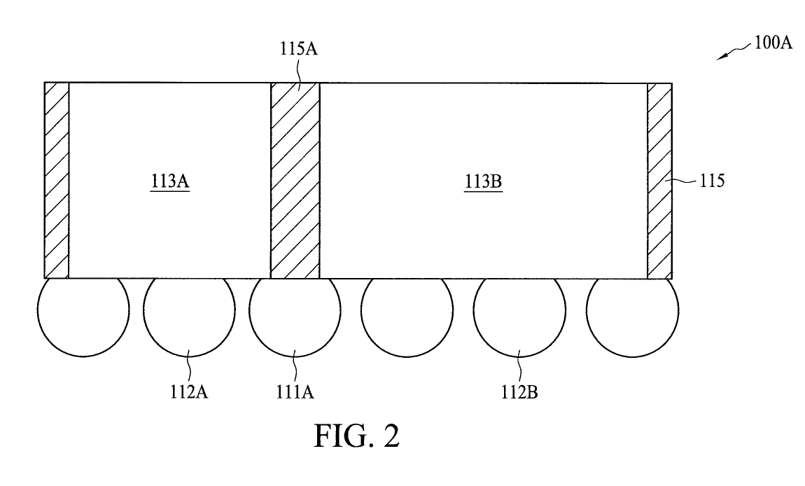

FIG. 2 is a cross-sectional view of a semiconductor package 100A in accordance with some embodiments of the present disclosure. In some embodiments, the semiconductor package 100A comprises: a first semiconductor device 113A; a second semiconductor device 113B laterally adjacent to the first semiconductor device 113A; a molding member 115 encapsulating the first semiconductor device 113A and the second semiconductor device 113B; and a bump structure 111A implementing a lateral signal path between the first semiconductor device 113A and the second semiconductor device 113B. In some embodiments, a portion 115A of the molding member 115 is disposed between the first semiconductor device 113A and the second semiconductor device 113B, and the bump structure 111A extends laterally across the portion 115A of the molding member 115.

In some embodiments, the first semiconductor device 113A and the second semiconductor device 113B are two adjacent chips of a single wafer. In some embodiments, the first semiconductor device 113A and the second semiconductor device 113B are two chips from different wafers. In some embodiments, the semiconductor package 100A further comprises a vertical bump structure 112A implementing a vertical signal path of the first semiconductor device 113A and a vertical bump structure 112B implementing a vertical signal path of the second semiconductor device 113B. In contrast to the vertical bump structures 112A and 112B, the bump structure 111A is considered a lateral bump structure implementing lateral signal path.

In some embodiments, the bump structure 111A implements the lateral signal path between the first semiconductor device 113A and the second semiconductor device 113B in the absence of a redistribution structure corresponding to the redistribution layer 11 shown in FIG. 1. Consequently, the height of the semiconductor package 100A in FIG. 2 is less than the height of the semiconductor package 10 in FIG. 1. In other words, the semiconductor package 100A in FIG. 2 can meet the miniaturized scale demand (small form factor) of the semiconductor packages. In addition, the absence of a redistribution structure corresponding to the redistribution layer 11 shown in FIG. 1 is a key factor in the reduction of the fabrication cost of the semiconductor package 100A in FIG. 2.

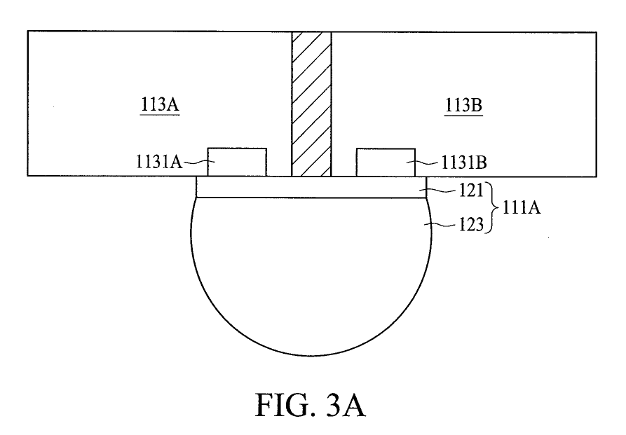

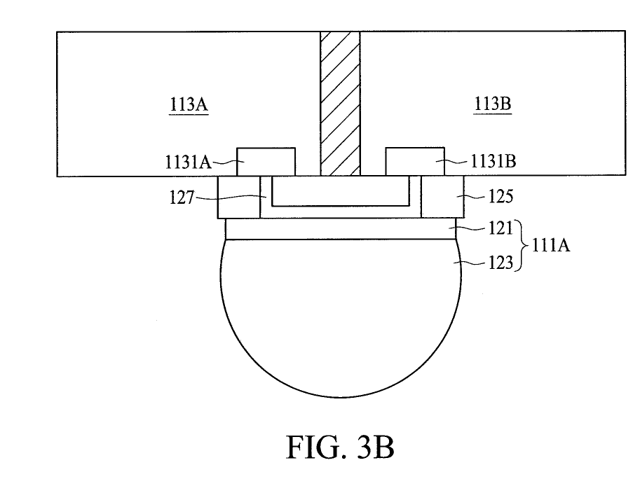

FIG. 3A is a cross-sectional view of the lateral signal path implemented by the bump structure 111A in accordance with some embodiments of the present disclosure. In some embodiments, the bump structure 111A include an under bump metallization 121 and a bump body 123 disposed over the under bump metallization 121. In some embodiments, the under bump metallization 121 of the bump structure 111A electrically connects a pad 1131A of the first semiconductor device 113 and a pad 1131B of the second semiconductor device 113B in the absence of a redistribution structure with dielectric layers.

In some embodiments, the under bump metallization 121 includes conductive material such as copper, gold, silver, nickel, solder, tin, lead, tungsten, aluminum, titanium, palladium, or alloys thereof. In some embodiments, the bump body 123 is solder ball, ball grid array (BGA) ball, controlled collapse chip connection (C4) bump, microbump, pillar, or the like. In some embodiments, the vertical bump structures 112A and 112B may have the same configuration as the bump structure 111A. In some embodiments, the bump structure 111A and the vertical bump structures 112A and 112B may have a spherical, hemispherical or cylindrical shape.

In some embodiments, a barrier layer and a seed layer (not shown in the drawings) may be optionally disposed between the under bump metallization 121 and the pad 1131A (or the pad 1131B). In some embodiments, the barrier layer is disposed over the pad 1131A (or the pad 1131B), and the seed layer is disposed over the barrier layer. In some embodiments, the barrier layer is configured to prevent the element of the bump body 123 from diffusing into the pad 1131A (or the pad 1131B). In some embodiments, the barrier layer includes gold, silver, nickel, tin, lead, or the like. In some embodiments, the seed layer is configured to adhere the under bump metallization 121 to the pad 1131A (or the pad 1131B). In some embodiments, the seed layer includes copper, gold, silver, nickel, solder, tin, lead, aluminum, titanium, or the like.

FIG. 3B is a cross-sectional view of an integrated signal path implemented by a bump structure 111A and a redistribution structure 125 in accordance with some embodiments of the present disclosure. In FIG. 3B, the lateral signal path of the integrated signal path is implemented by the redistribution structure 125 having a conductive line 127 electrically connecting the pad 1131A of the first semiconductor device 113A and the pad 1131B of the second semiconductor device 113B, and the vertical signal path of the integrated signal path is implemented by the bump structure 111A electrically connected to the conductive line 127 of the redistribution structure 125.

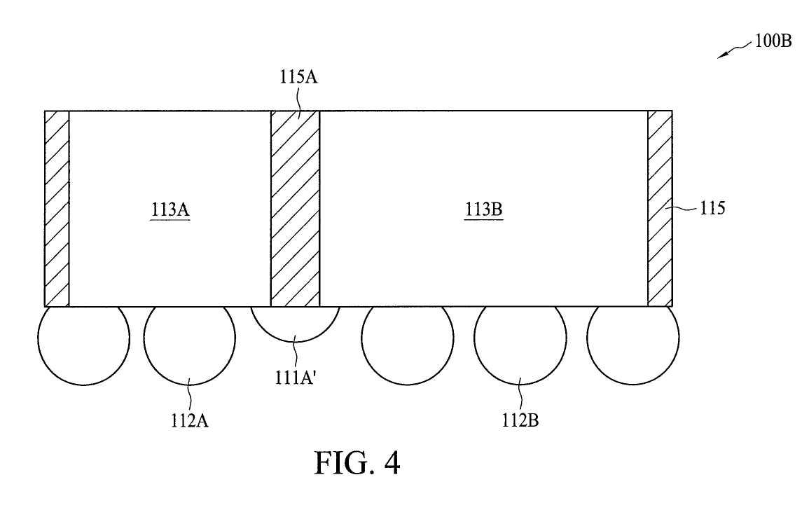

FIG. 4 is a cross-sectional view of a semiconductor package 100B in accordance with some embodiments of the present disclosure. The semiconductor package 100B shown in FIG. 4 is substantially the same as the semiconductor package 100A shown in FIG. 2, except for the size of the bump structure. In FIG. 2, the height of the vertical bump structures 112A and 112B is substantially the same as the height of the bump structure 111A, whereas in FIG. 4, the vertical bump structures 112A and 112B are higher than the bump structure 111A. In other words, in FIG. 4, the height of the vertical bump structures 112A and 112B is different from the height of the bump structure 111A.

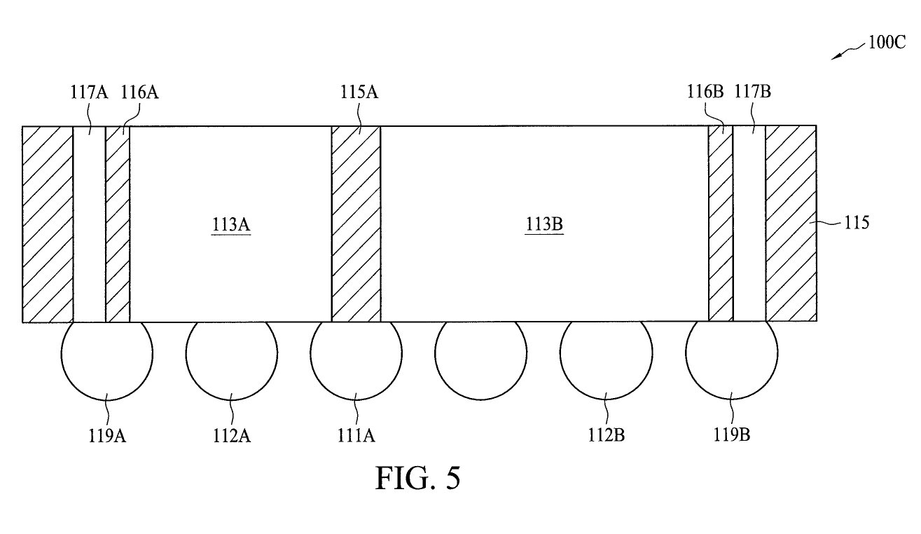

FIG. 5 is a cross-sectional view of a semiconductor package 100C in accordance with some embodiments of the present disclosure. Compared with the semiconductor package 100A in FIG. 2, the semiconductor package 100C in FIG. 5 further comprises a first conductive via 117A laterally adjacent to the first semiconductor device 113A, a second conductive via 117B laterally adjacent to the second semiconductor device 113B, a first bump structure 119A implementing a first lateral signal path between the first semiconductor device 113A and the first conductive via 117A, and a second bump structure 119B implementing a second lateral signal path between the second semiconductor device 113B and the second conductive via 117B. In addition, a portion 116A of the molding member 115 is disposed between the first semiconductor device 113A and the first conductive via 117A, and a portion 116B of the molding member 115 is disposed between the second semiconductor device 113B and the second conductive via 117B.

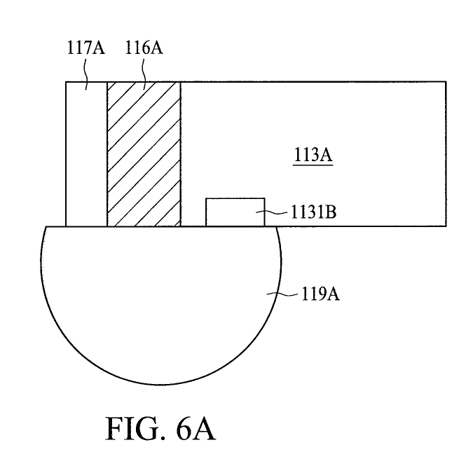

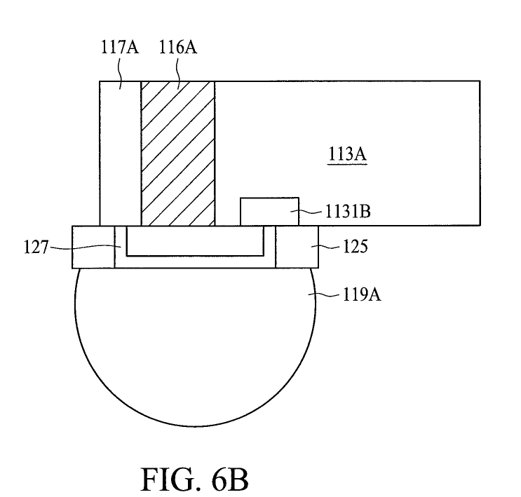

FIG. 6A is a cross-sectional view of the lateral signal path implemented by the first bump structure 119A in accordance with some embodiments of the present disclosure. In some embodiments, the first bump structure 119A is a bump body electrically connecting a pad 1131B of the first semiconductor device 113A and the first conductive via 117A in the absence of a redistribution structure, and the first bump structure 119A extends laterally across the portion 116A of the molding member 115. In some embodiments, the second bump structure 119B may use the same configuration as the first bump structure 119A.

FIG. 6B is a cross-sectional view of an integrated signal path implemented by a first bump structure 119A and a redistribution structure 125 in accordance with some embodiments of the present disclosure. In FIG. 6B, the lateral signal path of the integrated signal path is implemented by the redistribution structure 125 having a conductive line 127 electrically connecting the pad 1131B of the first semiconductor device 113A to the first conductive via 117A, and the vertical signal path of the integrated signal path is implemented by the bump structure 119A electrically connected to the conductive line 127 of the redistribution structure 125.

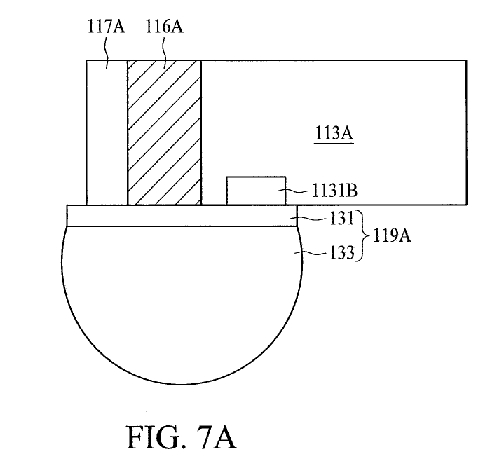

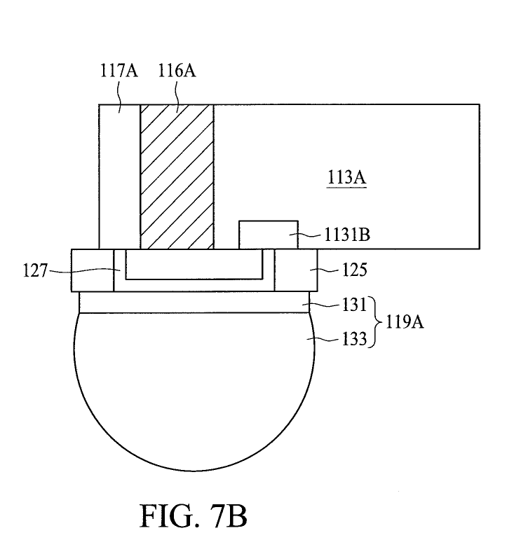

FIG. 7A is a cross-sectional view of the lateral signal path implemented by the first bump structure 119A in accordance with some embodiments of the present disclosure. In some embodiments, the first bump structure 119A includes an under bump metallization 131 and a bump body 133 disposed over the under bump metallization 131. In some embodiments, the under bump metallization 131 of the first bump structure 119A electrically connects a pad 1131B of the first semiconductor device 113A to the first conductive via 117A in the absence of a redistribution structure, and the under bump metallization 131 of the first bump structure 119A extends laterally across the portion 116A of the molding member 115. In some embodiments, the second bump structure 119B may use the same configuration as the first bump structure 119A.

FIG. 7B is a cross-sectional view of an integrated signal path implemented by a first bump structure 119A and a redistribution structure 125 in accordance with some embodiments of the present disclosure. In FIG. 7B, the lateral signal path of the integrated signal path is implemented by the redistribution structure 125 having a conductive line 127 electrically connecting the pad 1131B of the first semiconductor device 113A to the first conductive via 117A, and the vertical signal path of the integrated signal path is implemented by the bump structure 119A, wherein the under bump metallization 131 electrically connects to the conductive line 127 of the redistribution structure 125.

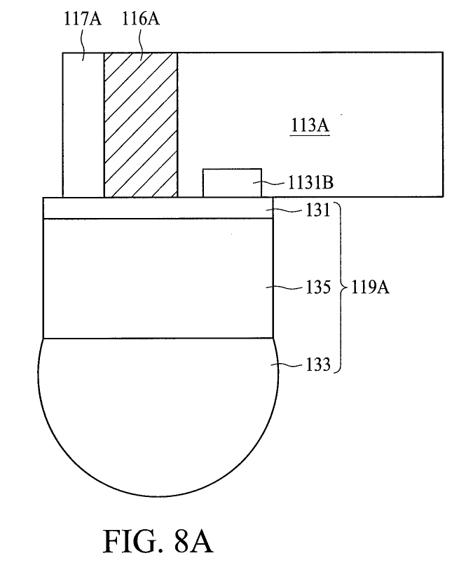

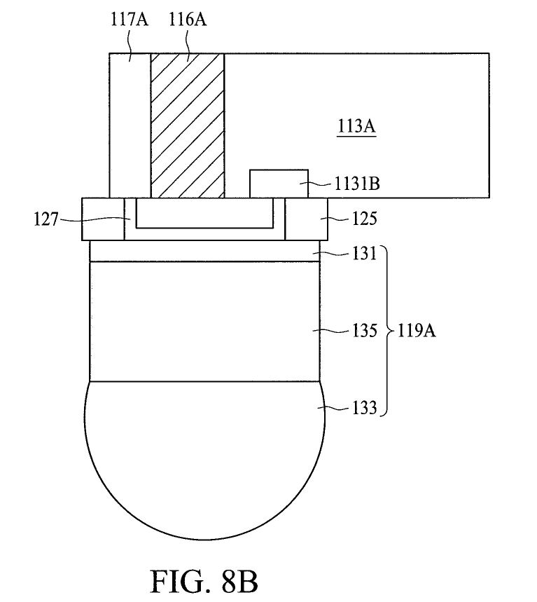

FIG. 8A is a cross-sectional view of the lateral signal path implemented by the first bump structure 119A in accordance with some embodiments of the present disclosure. In some embodiments, the first bump structure 119A include an under bump metallization 131, a conductive pillar 135 disposed over the under bump metallization 131, and a bump body 133 disposed over the conductive pillar 135. In some embodiments, the under bump metallization 131 of the first bump structure 119A electrically connects a pad 1131B of the first semiconductor device 113A to the first conductive via 117A in the absence of a redistribution structure, and the under bump metallization 131 of the first bump structure 119A extends laterally across the portion 116A of the molding member 115. In some embodiments, the second bump structure 119B may use the same configuration as the first bump structure 119A.

FIG. 8B is a cross-sectional view of an integrated signal path implemented by a first bump structure 119A and a redistribution structure 125 in accordance with some embodiments of the present disclosure. In FIG. 8B, the lateral signal path of the integrated signal path is implemented by the redistribution structure 125 having a conductive line 127 electrically connecting the pad 1131B of the first semiconductor device 113A to the first conductive via 117A, and the vertical signal path of the integrated signal path is implemented by the bump structure 119A, wherein the under bump metallization 131 electrically connects to the conductive line 127 of the redistribution structure 125.

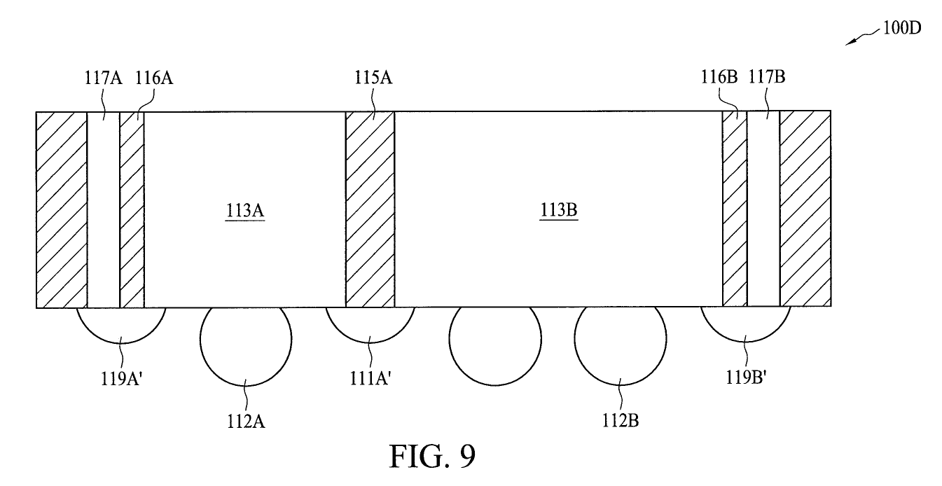

FIG. 9 is a cross-sectional view of a semiconductor package 100D in accordance with some embodiments of the present disclosure. The semiconductor package 100D shown in FIG. 9 is substantially the same as the semiconductor package 100C shown in FIG. 5, except for the size of the bump structure. In FIG. 5, the height of the vertical bump structures 112A and 112B is substantially the same as the height of the bump structures 111A, 119A, and 119B, whereas in FIG. 9, the vertical bump structures 112A and 112B are higher than the bump structures 111A′, 119A′, and 119B′.

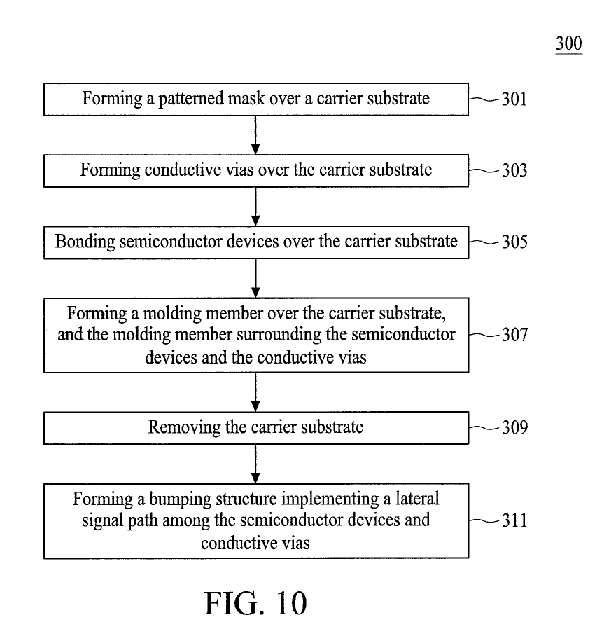

FIG. 10 is a flow chart of a method for preparing a semiconductor package in accordance with some embodiments of the present disclosure. In some embodiments, the semiconductor package can be formed by a method 300 of FIG. 10. The method 300 includes a number of operations and the description and illustration are not deemed as a limitation as the sequence of the operations. The method 300 includes a number of steps (301, 303, 305, 307, 309 and 311).

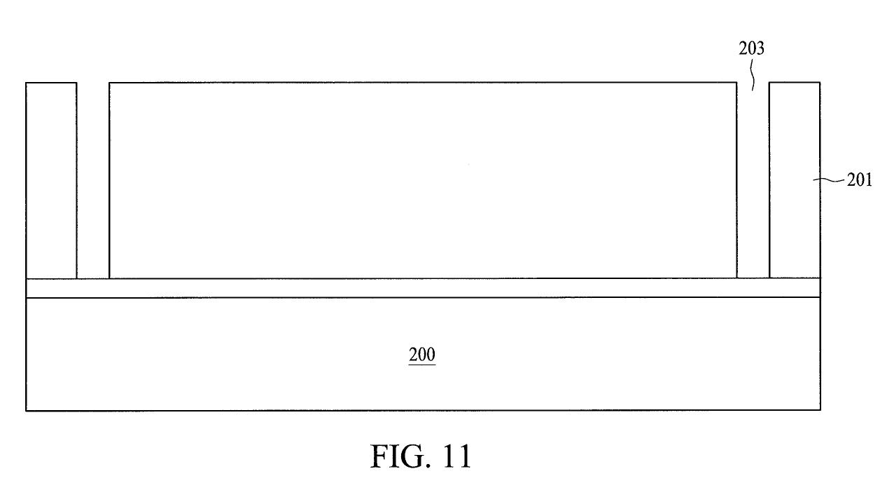

In step 301, a patterned mask 201 is formed over a carrier substrate 200 as shown in FIG. 11. In some embodiments, a lithographic process is performed to form the patterned mask 201 such as a photoresist layer with openings 203.

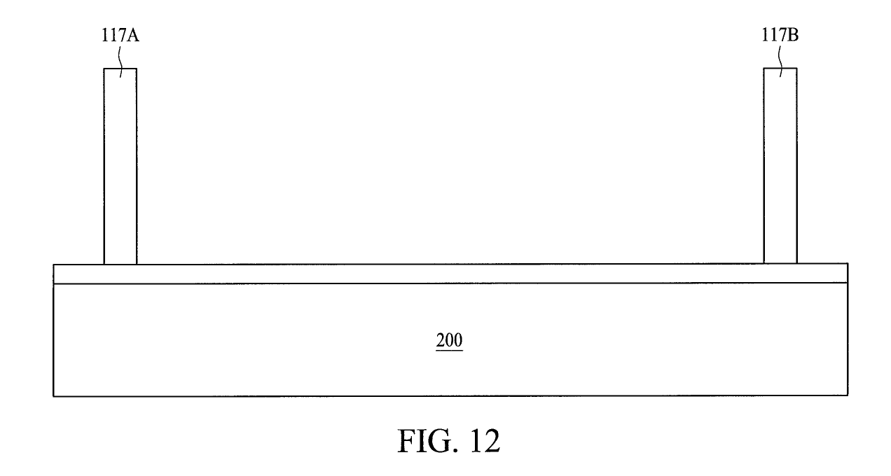

In step 303, several conductive vias 117A and 117B are formed in the openings 203 over the carrier substrate 200 as shown in FIG. 12, and the patterned mask 201 is then removed. In some embodiments, the conductive vias 117A and 117B are formed by a plating process or any other suitable process.

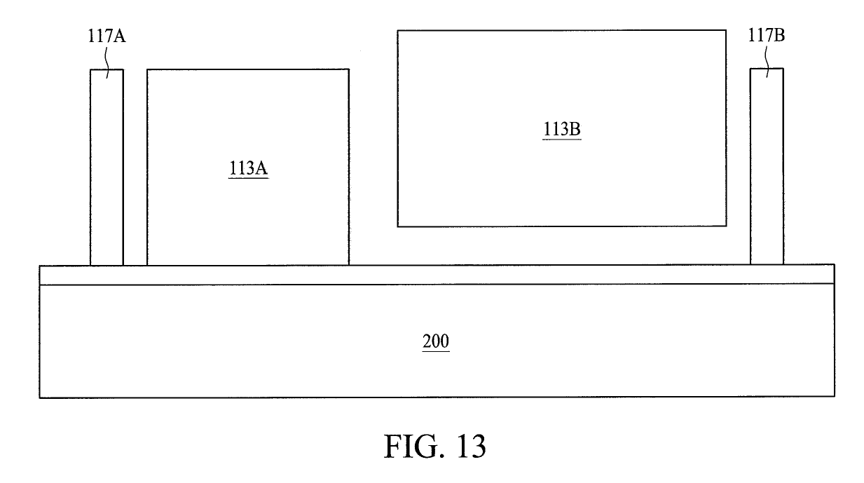

In step 305, semiconductor devices 113A and 113B are attached over the carrier substrate 200 as shown in FIG. 13. In some embodiments, the semiconductor devices 113A and 113B are laterally disposed between the conductive vias 117A and 117B via an adhesive or by a fusion bonding process.

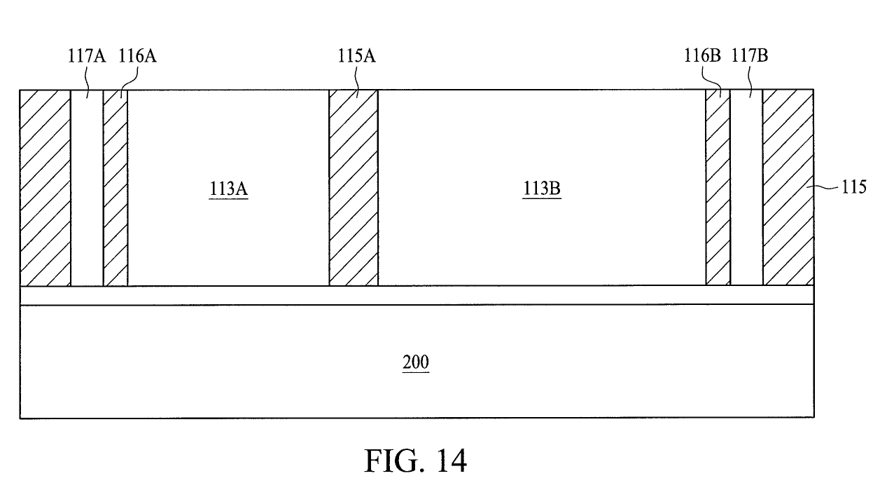

In step 307, a molding member 115 is forming over the carrier substrate 200, and the molding member 115 surrounds the semiconductor devices 113A and 113B and the conductive vias 117A and 117B as shown in FIG. 14. In some embodiments, a portion 115A of the molding member 115 is disposed between the semiconductor device 113A and the semiconductor device 113B, a portion 116A of the molding member 115 is disposed between the semiconductor device 113A and the conductive via 117A, and a portion 116B of the molding member 115 is disposed between the semiconductor device 113B and the conductive via 117B.

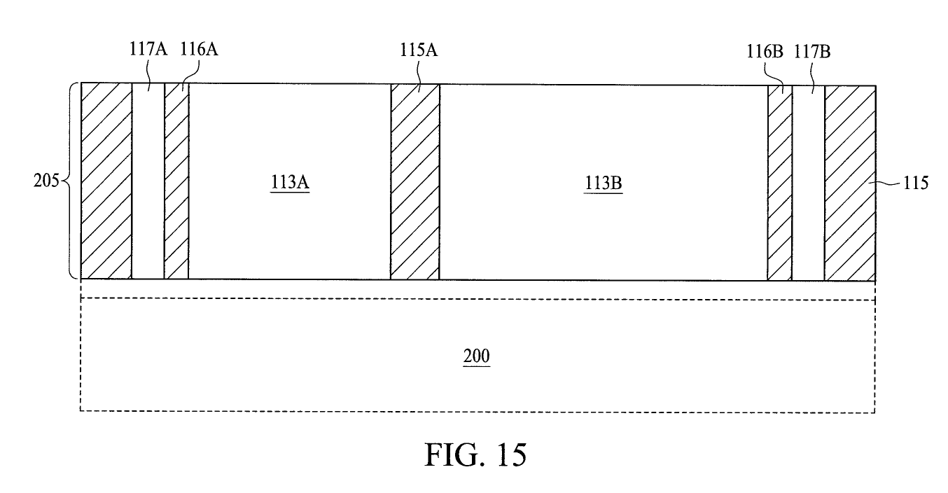

In step 309, the carrier substrate 200 is removed to form a molded device 205, as shown in FIG. 15. In some embodiments, a redistribution layer (not shown in this figure) may be optionally formed over the molded device 205, and the redistribution layer forms a portion of a lateral signal path.

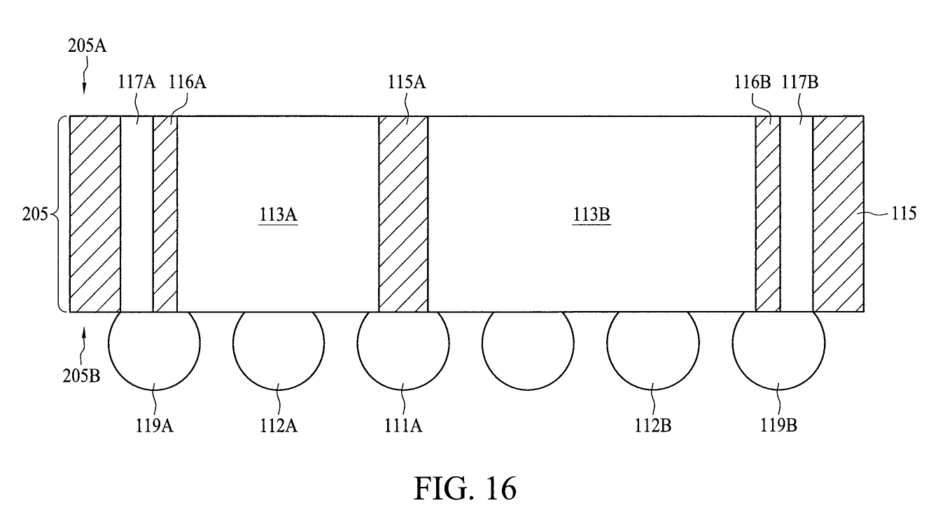

In step 311, several bump structures 111A, 112A, 119A, 112B, and 119B are formed over the molded device 205, as shown in FIG. 16. In some embodiments, the carrier substrate 200 is positioned on one side 205A of the molded device 205, while the bump structures 111A, 112A, 119A, 112B, and 119B are disposed on the other side 205B of the molded device 205. In some embodiments, the bump structures 111A, 112A, 119A, 112B, and 119B are disposed over the molded device 205 by electroplating, ball dropping, solder pasting, stencil printing or other suitable process.

The embodiments of the present disclosure provide a semiconductor package with a bump structure implementing the lateral signal path between the first device and the second device in the absence of a redistribution structure. Consequently, the height of the semiconductor package of the present disclosure is less than the height of the semiconductor package with a redistribution structure. In other words, the semiconductor package of the present disclosure can meet the miniaturized scale demand (small form factor) of the semiconductor packages. In addition, the absence of the redistribution structure is a key factor in the reduction of the fabrication cost of the semiconductor package.

In some embodiments, a semiconductor package includes: a first device; a second device laterally adjacent to the first device; a molding member encapsulating the first device and the second device, wherein a portion of the molding member is disposed between the first device and the second device; and a lateral bump structure implementing a lateral signal path between the first device and the second device.

In some embodiments, a semiconductor package includes: a first device; a second device laterally adjacent to the first device; a molding member encapsulating the first device and the second device, wherein a portion of the molding member is disposed between the first device and the second device; and an integrated signal path comprising a redistribution structure implementing a lateral signal path and a first bump structure implementing a first vertical signal path, wherein the redistribution structure comprises a conductive line electrically connecting the first device and the second device, and the first bump structure is electrically connected to the conductive line.

Although the present disclosure and its advantages have been described in detail, it should be understood that various changes, substitutions and alterations can be made herein without departing from the spirit and scope of the disclosure as defined by the appended claims. For example, many of the processes discussed above can be implemented through different methods, replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perforin substantially the same function or achieve substantially the same result as the corresponding embodiments described herein, may be utilized according to the present disclosure. Accordingly, the appended claims are intended to include within their scope such processes, machines, manufacture, compositions of matter, means, methods, or steps.

1. A semiconductor package, comprising:
a first device;
a second device laterally adjacent to the first device, the first device and the second device having a surface extending along a same plane;
a molding member encapsulating the first device and the second device, wherein a portion of the molding member is disposed between the first device and the second device;
a lateral bump structure implementing a lateral signal path between the first device and the second device, the lateral bump structure being disposed on the surface, the lateral bump structure comprising:
an under bump metallization electrically connecting the first device and the second device in absence of a redistribution structure; and
a single bump body disposed over the under bump metallization, the single bump body extending laterally across said portion of the molding member; and
a vertical bump structure, disposed on the surface, implementing a vertical signal path of the first device, wherein a height of the vertical bump structure is different from a height of the lateral bump structure.

2. The semiconductor package of claim 1, wherein the first device and the second device are two adjacent semiconductor chips of a single wafer.

3. The semiconductor package of claim 1, wherein the first device and the second device are two semiconductor chips from different wafers.

4. The semiconductor package of claim 1, wherein the first device is a semiconductor chip and the second device is a conductive via.

5. (canceled)

6. The semiconductor package of claim 1, wherein the lateral bump structure further comprises:
a conductive pillar disposed over the under bump metallization.

7. (canceled)

8. The semiconductor package of claim 1, wherein the vertical bump structure is higher than the lateral bump structure.

9. A semiconductor package, comprising:
a first device;
a second device laterally adjacent to the first device, the first device and the second device having a surface extending along a same plane;
a molding member encapsulating the first device and the second device, wherein a portion of the molding member is disposed between the first device and the second device; and
an integrated signal path comprising a redistribution structure implementing a lateral signal path and a first bump structure, the redistribution structure being disposed on the surface, implementing a first vertical signal path,
wherein the redistribution structure comprises a conductive line electrically connecting the first device and the second device, and the first bump structure is electrically connected to the conductive line, and
wherein the first bump structure is disposed on a surface of the redistribution layer opposite to said surface extending along the same plane and comprises:
an under bump metallization electrically connecting the first device and the second device; and
a bump body disposed over the under bump metallization.

10. The semiconductor package of claim 9, wherein the first device and the second device are two adjacent semiconductor chips of a single wafer.

11. The semiconductor package of claim 9, wherein the first device and the second device are two semiconductor chips from different wafers.

12. The semiconductor package of claim 9, wherein the first device is a semiconductor chip and the second device is a conductive via.

13. (canceled)

14. The semiconductor package of claim 9, wherein the first bump structure further comprises:
a conductive pillar disposed over the under bump metallization.

15. (canceled)

16. The semiconductor package of claim 9, wherein the second bump structure is higher than the first bump structure.
